(19) United States
(12) Patent Application Publication
(10) Pub. No.: US 2025/0012834 A1
(43) Pub. Date: Jan. 9, 2025

(54) NON-CONTACT VOLTAGE MEASURING METHOD AND SYSTEM THEREOF

(71) Applicant: Qisda Corporation, Taoyuan City (TW)

(72) Inventors: Yaow-Ming Chen, Taoyuan City (TW); Hung-Yi Lee, Taoyuan City (TW); Hsueh-Ju Wu, Taoyuan City (TW); Yuan Tseng, Taoyuan City (TW)

(73) Assignee: Qisda Corporation, Taoyuan City (TW)

(21) Appl. No.: 18/668,274

(22) Filed: May 20, 2024

(30) Foreign Application Priority Data
Jul. 6, 2023 (CN) 202310826709.6

(51) Int. Cl. G01R 19/25

(52) U.S. Cl. CPC G01R 19/2503; G01R 19/2509

(57) ABSTRACT

A non-contact voltage measuring method and a non-contact voltage measuring system are provided. The non-contact voltage measuring method includes the following steps: measuring a voltage signal source to be measured through a capacitive coupling structure to generate a measurement signal; generating an output signal based on the measurement signal through a signal processing circuit; analyzing the output signal through a sampling unit to generate a sampled signal; and outputting the sampled signal to the trained artificial intelligence model, so that the trained artificial intelligence model outputs a recovery signal.

### CROSS-REFERENCE TO RELATED APPLICATION

This application claims the priority benefit of China application serial no. 202310826709.6, filed on Jul. 6, 2023. The entirety of the above-mentioned patent application is hereby incorporated by reference herein and made a part of this specification.

### BACKGROUND

### Technical Field

The disclosure relates to a voltage measurement technique, and in particular, to a non-contact voltage measuring method and a system thereof.

### Description of Related Art

In the electrical engineering-related field, electrical signals are typically important measurement data in electrical systems. However, the general measurement method is to measure the metal trace in the system through contact-type voltage and/or current sensors, so there is a higher risk during measurement. In this regard, an electric shock accident may easily occur since the user uses the sensor improperly, for example, or high voltage exists in the measured object or the measured environment. Therefore, how to measure electrical signals safely, effectively and accurately is an important research topic in the field.

### SUMMARY

The disclosure provides a non-contact voltage measuring method and a non-contact voltage measuring system, which may effectively measure a voltage signal source to be measured.

A non-contact voltage measuring method of the disclosure includes the following steps. A voltage signal source to be measured is measured through a capacitive coupling structure to generate a measurement signal. An output signal is generated based on the measurement signal through a signal processing circuit. The output signal is analyzed through a sampling unit to generate a sampled signal. The sampled signal is outputted to a trained artificial intelligence model, so that the trained artificial intelligence model outputs a recovery signal.

A non-contact voltage measuring system of the disclosure includes a capacitive coupling structure, a signal processing circuit and an operational circuit. The capacitive coupling structure is used to measure a voltage signal source to be measured to generate a measurement signal. The signal processing circuit is electrically connected to the capacitive coupling structure to generate an output signal based on the measurement signal. The operational circuit is electrically connected to the signal processing circuit and includes a sampling unit and a trained artificial intelligence model. The sampling unit is used to analyze the output signal to generate a sampled signal. The trained artificial intelligence model is used to receive the sampled signal and output a recovery signal.

Based on the above, the non-contact voltage measuring method and the non-contact voltage measuring system of the disclosure may measure non-contact voltage in a non-contact manner through a capacitive coupling structure, and utilize a trained artificial intelligence model to generate accurate measurement results.

In order for the features and advantages of the disclosure to be more comprehensible, the following specific embodiments are described in detail in conjunction with the drawings.

### BRIEF DESCRIPTION OF THE DRAWINGS

FIG. 1 is a schematic diagram of a non-contact voltage measuring system according to an embodiment of the disclosure.

FIG. 2 is a schematic diagram of non-contact voltage measurement according to an embodiment of the disclosure.

FIG. 3 is a flow chart of a non-contact voltage measuring method according to an embodiment of the disclosure.

FIG. 4 is a schematic diagram of a measurement signal according to an embodiment of the disclosure.

FIG. 5 is a schematic diagram of an output signal according to an embodiment of the disclosure.

FIG. 6 is a schematic diagram of a recovery signal according to an embodiment of the disclosure.

FIG. 7 is a schematic diagram of a target signal according to an embodiment of the disclosure.

FIG. 8 is a flow chart of generating a recovery signal according to an embodiment of the disclosure.

### DESCRIPTION OF THE EMBODIMENTS

To provide a further understanding of the content of the invention, embodiments will be provided below as examples for implementing the invention accordingly. In addition, wherever possible, elements, components, and steps labeled with the same reference numerals in the drawings and embodiments refer to the same or similar components.

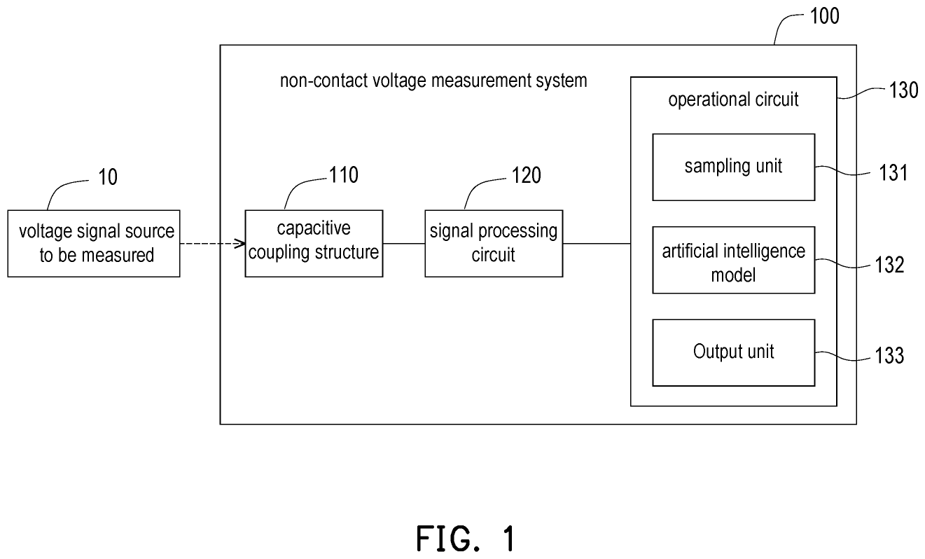

FIG. 1 is a schematic diagram of a non-contact voltage measuring system according to an embodiment of the disclosure. Referring to FIG. 1, a non-contact voltage measuring system 100 includes a capacitive coupling structure 110, a signal processing circuit 120 and an operational circuit 130. The capacitive coupling structure 110 is electrically connected to the signal processing circuit 120. The signal processing circuit 120 is electrically connected to the operational circuit 130. In this embodiment, the capacitive coupling structure 110 may be a plate capacitor and may be used to measure a voltage signal source 10 to be measured. The voltage signal source 10 to be measured may include, for example, a signal source and a signal line. The capacitive coupling structure 110 may measure a voltage signal transmitted by the signal source through the signal line without direct contact with a metal trace of the signal line.

In the embodiment, the signal processing circuit 120 may include an analog-to-digital converter (ADC) circuit, a filter circuit, a signal amplifier circuit, and relevant analog and/or digital circuits, etc., but the disclosure is not limited thereto. In the embodiment, the operational circuit 130 may include a sampling unit 131, an artificial intelligence model 132 and an output unit 133.

The operational circuit 130 may include, for example, a processor and a storage device. The processor may be, for example, a central processing unit (CPU), a microprocessor control unit (MCU), a field programmable gate array (FPGA) or the like, or a chip having data processing functions, but the disclosure is not limited thereto. The storage device may be, for example, a memory, wherein the memory may be, for example, read only memory (ROM), erasable programmable read only memory (EPROM), random access memory (RAM), semiconductor memory, other volatile memory or non-volatile memory, and may be used to store relevant algorithms or programs of the sampling unit 131, the artificial intelligence model 132 and the output unit 133, and may further store or temporarily store various parameters, data, signals and models provided by the disclosure. In an embodiment, the sampling unit 131, the artificial intelligence model 132 and the output unit 133 may also be achieved by digital circuits.

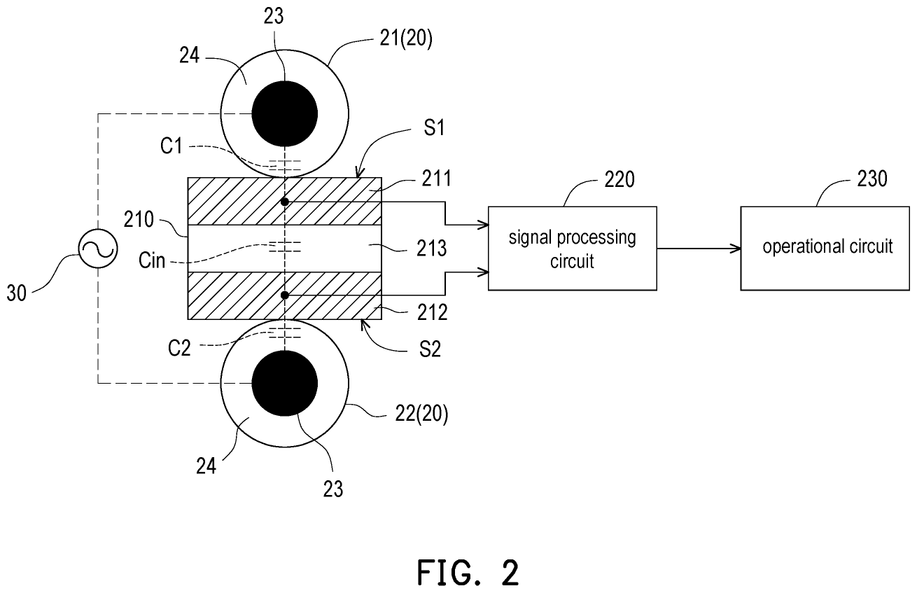

FIG. 2 is a schematic diagram of non-contact voltage measurement according to an embodiment of the disclosure. The non-contact voltage measuring system 100 in FIG. 1 may be implemented as a structure as shown in FIG. 2, and the capacitive coupling structure 110 may be implemented as a plate capacitor 210 in FIG. 2. Referring to FIG. 2, FIG. 2 is a schematic side view of the plate capacitor 210. In this embodiment, a voltage signal source 30 to be measured may be an alternating current signal (such as a mains signal), and the alternating current signal may be transmitted through the signal line 20. In the embodiment, the plate capacitor 210 may be formed by stacking an upper plate electrode 211, a lower electrode plate 212 and a dielectric layer 213, and the entire outer layer is coated with an insulating material (not shown) to form a first insulating surface S1 and a second insulating surface S2. The signal line 20 includes a first line segment 21, a second line segment 22, a metal trace (wire) 23 and an insulating layer 24, wherein the insulating layer 24 is wrapped around the metal trace 23. The upper electrode plate 211 and the lower electrode plate 212 of the plate capacitor 210 are electrically connected to a signal processing circuit 220 to provide measurement signals to the signal processing circuit 220. The signal processing circuit 220 is electrically connected to the operational circuit 230.

In this embodiment, the first insulating surface S1 of the plate capacitor 210 may be in contact with the first line segment 21 of the signal line 20, and the second insulating surface S2 of the plate capacitor 210 may be in contact with the second line segment 22 of the signal line 20. For example, the user may bend the signal line 20 so that the two line segments of the signal line 20 contact the first insulating surface S1 and the second insulating surface S2 of the plate capacitor 210, respectively, and form effective overlapping areas, respectively. In this way, the insulating material between the metal trace 23 and the upper electrode plate 211 and lower electrode plate 212 of the plate capacitor 210 respectively forms stray capacitance C1 and stray capacitance C2. In this regard, the stray capacitance C1, the stray capacitance C2, the capacitance Cin of the plate capacitor 210 itself and the equivalent impedance (Rin) of the signal processing circuit 220 may form a circuit loop, so that the AC signal of the voltage signal source 30 to be measured may transfer energy the signal processing circuit 220 in a manner of capacitive coupling. In other words, the plate capacitor 210 of this embodiment does not need to be electrically connected to a ground terminal or a system reference point to measure the voltage signal source 30 to be measured.

In the embodiment, a transfer function Gᵥ₋ᵥ(s), a transfer function Gᵥ₋ᵢ(s), a gain relationship Gᵥ₋ᵥ (ω), a gain relationship Gᵥ₋ᵢ(ω), a phase relationship θᵥ₋ᵥ(ω), a phase relationship θᵥ₋ᵢ(ω) between the voltage signal source 30 to be measured and the input voltage (Vin) of the signal processing circuit 220, may be described by Equation (1) to Equation (6) as follows, for example. In the following equations, the symbol “s” represents the frequency parameter of the Laplace transform. The symbol “w” is the frequency parameter of common spectrum analysis. The symbol “v” represents the voltage variable. The symbol “i” represents the current variable. Taking spectrum analysis as an example, the gain relationship Gᵥ₋ᵥ (ω) is the gain change from the voltage to be measured to the input voltage Vin. The phase relationship θᵥ₋ᵥ(ω)) is the phase change from the voltage to be measured to the input voltage Vin. The gain relationship Gᵥ₋ᵢ(ω) is the gain change from the voltage to be measured to the input voltage Vin. The phase relationship θᵥ₋ᵢ(ω) is the phase change from the voltage to be measured to the input voltage Vin.

$${G}_{v - v} ( s ) = \frac{sRin \frac{{C}_{1} {C}_{2}}{{C}_{1} + {C}_{2}}}{1 + sRin [ Cin + \frac{{C}_{1} {C}_{2}}{{C}_{1} + {C}_{2}} ]} \qquad Equation ( 1 )$$

$${G}_{v - i} ( s ) = \frac{s \frac{{C}_{1} {C}_{2}}{{C}_{1} + {C}_{2}}}{1 + sRin [ Cin + \frac{{C}_{1} {C}_{2}}{C 1 + C 2} ]} \qquad Equation ( 2 )$$

$${G}_{v - v} ( ω ) = \frac{ω Rin \frac{{C}_{1} {C}_{2}}{{C}_{1} + {C}_{2}}}{\sqrt{1 + {[ ω Rin [ Cin + \frac{{C}_{1} {C}_{2}}{{C}_{1} + {C}_{2}} ] ]}^{2}}} \qquad Equation ( 3 )$$

$${G}_{v - i} ( ω ) = \frac{ω \frac{{C}_{1} {C}_{2}}{{C}_{1} + {C}_{2}}}{\sqrt{1 + {[ ω Rin [ Cin + \frac{{C}_{1} {C}_{2}}{C 1 + C 2} ] ]}^{2}}} \qquad Equation ( 4 )$$

$${θ}_{v - v} ( ω ) = 90 ° - \frac{180 °}{π} arctan ( ω Rin [ Cin + \frac{{C}_{1} {C}_{2}}{{C}_{1} + {C}_{2}} ] ) \qquad Equation ( 5 )$$

$${θ}_{v - i} ( ω ) = 90 ° - \frac{180 °}{π} arctan ( ω Rin [ Cin + \frac{{C}_{1} {C}_{2}}{{C}_{1} + {C}_{2}} ] ) \qquad Equation ( 6 )$$

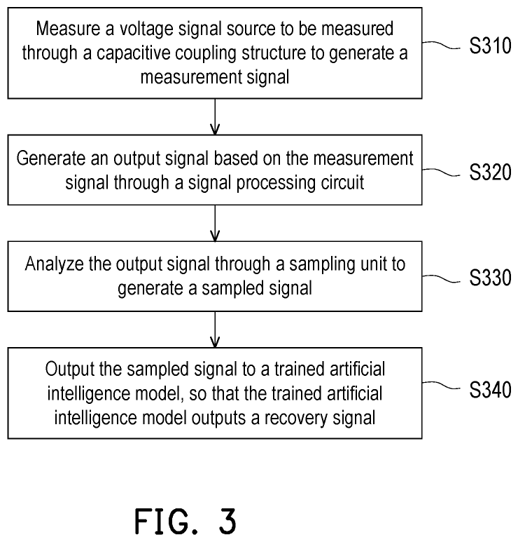

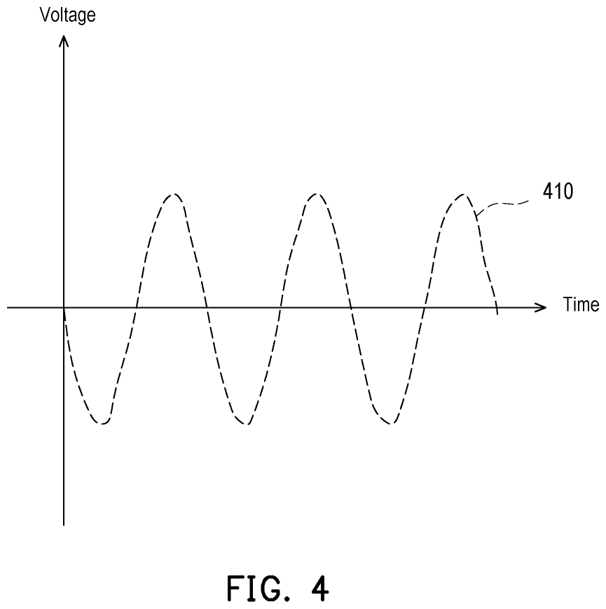

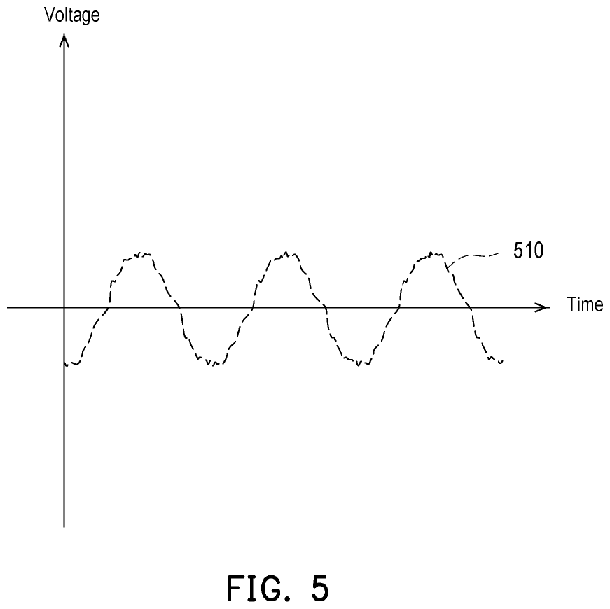

FIG. 3 is a flow chart of a non-contact voltage measuring method according to an embodiment of the disclosure. Referring to FIG. 1 and FIG. 3, the non-contact voltage measuring system 100 performs the following steps S310 to S340. In step S310, the non-contact voltage measuring system may measure the voltage signal source 10 to be measured through the capacitive coupling structure 110 to generate a measurement signal. Referring to FIG. 4, FIG. 4 is a schematic diagram of a measurement signal according to an embodiment of the disclosure. In this embodiment, the capacitive coupling structure 110 may output a measurement signal 410 as shown in FIG. 4. In step S320, the signal processing circuit 120 may generate an output signal based on the measurement signal. The signal processing circuit 120 may output the output signal to the sampling unit 131. Referring to FIG. 5, FIG. 5 is a schematic diagram of an output signal according to an embodiment of the disclosure. In the embodiment, the signal processing circuit 120 may, for example, perform analog signal processing on the measurement signal 410 shown in FIG. 4, such as signal conversion (for example, adjusting the range of signal voltage), signal filtering, and/or signal amplification, etc., on the measurement signal 410, to generate an output signal 510 as shown in FIG. 5, but the disclosure is not limited thereto. The signal processing circuit 120 is used to enhance the signal of the measurement signal 410 and maintain the waveform characteristics of the original signal, so as to facilitate subsequent signal sampling.

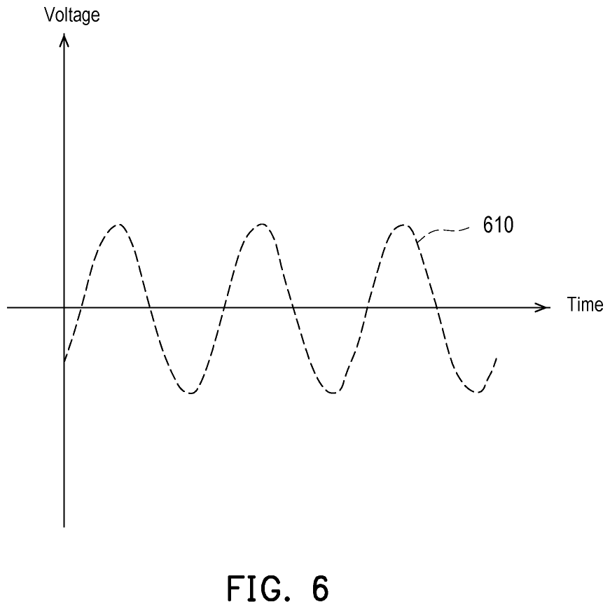

In step S330, the sampling unit 131 may analyze the output signal to generate a sampled signal. In this embodiment, the sampling unit 131 may, for example, perform analog-to-digital conversion on the output signal 510 shown in FIG. 5 to generate the sampled signal (i.e., a digital signal). In step S340, the sampling unit 131 may output the sampled signal to the trained artificial intelligence model 132, so that the trained artificial intelligence model 132 outputs a recovery signal. Referring to FIG. 6, FIG. 6 is a schematic diagram of a recovery signal according to an embodiment of the disclosure. In the embodiment, the trained artificial intelligence model 132 may generate amplitude parameters, phase parameters and frequency parameters based on the sampled signal. The trained artificial intelligence model 132 may generate a recovery signal 610 as shown in FIG. 6 based on the amplitude parameters, the phase parameters and the frequency parameters. The trained artificial intelligence model 132 may perform functions such as amplitude recovery, phase identification, frequency tracking and waveform reconstruction.

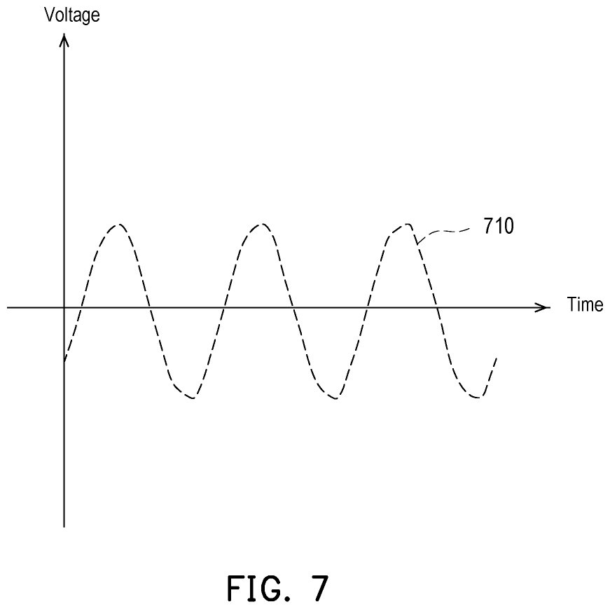

In this embodiment, the trained artificial intelligence model 132 may include a signal recovery model. The signal recovery model may be used to generate the recovery signal 610 based on the sampled signal. The signal recovery model may include a plurality of adjustable parameters, and the adjustable parameters include at least one of a weight parameter, an offset parameter, and a nonlinear function. In one embodiment, referring to FIG. 7, FIG. 7 is a schematic diagram of a target signal according to an embodiment of the disclosure. The operational circuit 130 may compare the recovery signal 610 with a corresponding target signal 710 as shown in FIG. 7 to generate a comparison result, and perform optimization training on the adjustable parameters based on the comparison result and optimized algorithm. In other words, during the training process, the artificial intelligence model 132 may train and optimize the adjustable parameters so that the trained artificial intelligence model 132 may achieve accurate signal recovery functions. For example, the aforementioned gain relationships Gᵥ₋ᵥ(ω) and Gᵥ₋ᵢ(ω) may be used to optimize parameters relevant to amplitude recovery functions, and the aforementioned phase relationships θᵥ₋ᵥ(ω) and θᵥ₋ᵢ(ω) may be used to optimize parameters relevant to phase identification functions, and other optimizations, so as to obtain a more accurate artificial intelligence model 132 through training.

In this embodiment, the artificial intelligence model 132 may provide the recovery signal 610 to the output unit 133. Depending on the user's need, the output unit 133 may select and output measurement results such as waveform-time data or waveform measurement characteristic values based on the aforementioned adjustable parameters to the user, and may, for example, display values relevant to the measurement results and waveforms on a monitor, but the disclosure is not limited thereto.

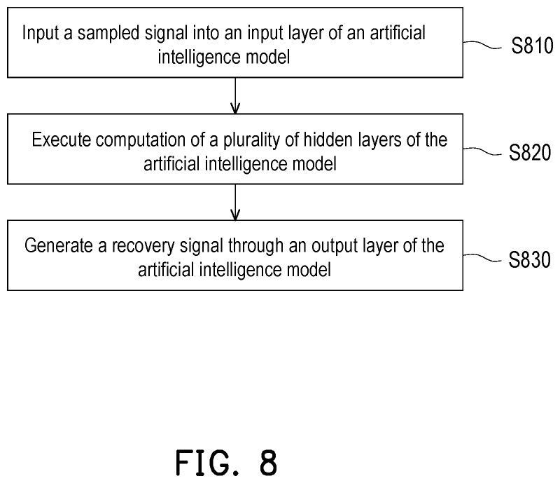

FIG. 8 is a flow chart of generating a recovery signal according to an embodiment of the disclosure. Referring to FIG. 1 and FIG. 8, the trained artificial intelligence model 132 may perform the following steps S810 to S830 to generate a recovery signal. In this embodiment, the artificial intelligence model 132 may include an input layer, a plurality of hidden layers, and an output layer.

In step S810, the operational circuit 130 may input the sampled signal to the input layer of the artificial intelligence model 132. The artificial intelligence model 132 may, for example, first perform a down-sampling function to first decrease the sampling rate of the sampled signal (digital signal) of N-dimensional length to reduce the data size to the data of M-dimensional length, wherein N is greater than M, and N and M are positive integers. In this way, it may effectively save the memory size required for each of the hidden layers later as well as the computational resources, so that the process may be executed in an operational circuit of lower computational power.

In step S820, the operational circuit 130 may perform operations on the plurality of hidden layers of the artificial intelligence model 132. The plurality of hidden layers may include, for example, a phase-identification-and-frequency-tracking subnetwork, a coupling structure weight subnetwork, an amplitude recovery atomic network, etc. The phase-identification-and-frequency-tracking sub-network may, for example, be used to identify the phase characteristics of the signal to be measured in real time and provide feedback for the frequency of the signal to be measured in real time. The coupling structure weight subnetwork may be used to infer the system characteristic parameters of the coupling structure, so that the artificial intelligence model 132 may consider the influence of the coupling structure to improve the accuracy of the recovery signal. The amplitude reduction atom network may be used to recover the fundamental wave amplitude of the signal to be measured and the waveforms and values of its harmonic amplitude component. In this regard, the subnetworks of different hidden layers may be achieved by different nonlinear functions, and the nonlinear functions may include optimized weight parameters, offset parameters, etc.

In step S830, the operational circuit 130 may generate a recovery signal through the output layer of the artificial intelligence model 132. The artificial intelligence model 132 may, for example, perform an up-sampling function to restore the original down-sampled and processed signal of M-dimensional length to the recovery signal of N-dimensional length. Therefore, the artificial intelligence model 132 of this embodiment may achieve an effective signal recovery function.

In addition, in one embodiment, the artificial intelligence model 132 may also include a data generation model. The data generation model may be used to generate an simulated voltage source and calculate an simulated sampled signal based on the capacitive coupling structure 110 and the transfer functions (G(s)) of the signal processing circuit 120, and may, for example, cooperate with the corresponding target signal 710 as shown in FIG. 7 to establish a training data set, so as to effectively validate the training results of the artificial intelligence model 132 during the training process. As such, during the model training process, the artificial intelligence model 132 may generate a corresponding reference recovery signal based on the simulated sampled signal, and the operational circuit 130 may effectively train the artificial intelligence model 132 by comparing the reference recovery signal with the target signal.

In summary, the non-contact voltage measuring method and the non-contact voltage measuring system of the disclosure may measure the original voltage signal of the voltage signal source to be measured in a non-contact manner and may accurately perform signal recovery on the measurement signal through the trained artificial intelligence model. In other words, corresponding to the original voltage signal of the voltage signal source to be measured, the recovery signal generated by recovering the measurement signal through the artificial intelligence model of the disclosure has a high degree of recovery, so that the recovery signal may be effectively used in subsequent signal processing and/or signal analysis.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A non-contact voltage measuring method, comprising:
measuring a voltage signal source to be measured through a capacitive coupling structure to generate a measurement signal;
generating an output signal based on the measurement signal through a signal processing circuit;
analyzing the output signal through a sampling unit to generate a sampled signal; and
outputting the sampled signal to a trained artificial intelligence model, so that the trained artificial intelligence model outputs a recovery signal.

2. The non-contact voltage measuring method according to claim 1, wherein the capacitive coupling structure comprises:
a plate capacitor, having a first insulating surface and a second insulating surface,
wherein the first insulating surface of the plate capacitor is in contact with a first line segment of a signal line of the voltage signal source to be measured, and the second insulating surface of the plate capacitor is in contact with a second line segment of the signal line of the voltage signal source to be measured.

3. The non-contact voltage measuring method according to claim 1, wherein the step of generating the output signal comprises:
performing analog signal processing on the output signal through the signal processing circuit.

4. The non-contact voltage measuring method according to claim 1, wherein the step of generating the output signal comprises:
filtering the output signal through the signal processing circuit.

5. The non-contact voltage measuring method according to claim 1, wherein the step of generating the output signal comprises:
amplifying the output signal through the signal processing circuit.

6. The non-contact voltage measuring method according to claim 1, wherein the step of generating the sampled signal comprises:
performing an analog-to-digital conversion on the output signal to generate the sampled signal.

7. The non-contact voltage measuring method according to claim 1, wherein the trained artificial intelligence model comprises a signal recovery model, the signal recovery model comprises a plurality of adjustable parameters, and the adjustable parameters comprises at least one of a weight parameter, an offset parameter and a nonlinear function, wherein the signal recovery model is used to generate the recovery signal based on the sampled signal.

8. The non-contact voltage measuring method according to claim 7, further comprising:
comparing the recovery signal with a corresponding target signal to generate a comparison result.

9. The non-contact voltage measuring method according to claim 7, wherein the trained artificial intelligence model further comprises a data generation model, wherein the data generation model is used to generate an simulated voltage source and to calculate an simulated sampled signal based on the capacitive coupling structure and a transfer function of the signal processing circuit, wherein the simulated voltage source and the simulated sampled signal are used to train the signal recovery model.

10. The non-contact voltage measuring method according to claim 1, wherein the step of outputting the recovery signal comprises:
generating an amplitude parameter, a phase parameter and a frequency parameter based on the sampled signal through the trained artificial intelligence model; and
generating the recovery signal based on the amplitude parameter, the phase parameter and the frequency parameter through the trained artificial intelligence model.

11. A non-contact voltage measuring system, comprising:
a capacitive coupling structure, used to measure a voltage signal source to be measured to generate a measurement signal;
a signal processing circuit, electrically connected to the capacitive coupling structure to generate an output signal based on the measurement signal; and
an operational circuit, electrically connected to the signal processing circuit and comprising:
a sampling unit, used to analyze the output signal to generate a sampled signal; and
a trained artificial intelligence model, used to receive the sampled signal and output a recovery signal.

12. The non-contact voltage measuring system according to claim 11, wherein the capacitive coupling structure comprises:
a plate capacitor, having a first insulating surface and a second insulating surface,
wherein the first insulating surface of the plate capacitor is in contact with a first line segment of a signal line of the voltage signal source to be measured, and the second insulating surface of the plate capacitor is in contact with a second line segment of the signal line of the voltage signal source to be measured.

13. The non-contact voltage measuring system according to claim 11, wherein the signal processing circuit performs analog signal processing on the output signal.

14. The non-contact voltage measuring system according to claim 11, wherein the signal processing circuit filters the output signal.

15. The non-contact voltage measuring system according to claim 11, wherein the signal processing circuit amplifies the output signal.

16. The non-contact voltage measuring system according to claim 11, wherein the sampling unit performs an analog-to-digital conversion on the output signal to generate the sampled signal.

17. The non-contact voltage measuring system according to claim 11, wherein the trained artificial intelligence model comprises a signal recovery model, the signal recovery model comprises a plurality of adjustable parameters, and the adjustable parameters comprise at least one of a weight parameter, an offset parameter, and a nonlinear function, wherein the signal recovery model is used to generate the recovery signal based on the sampled signal.

18. The non-contact voltage measuring system according to claim 17, wherein the operational circuit compares the recovery signal with a corresponding target signal to generate a comparison result.

19. The non-contact voltage measuring system according to claim 17, wherein the trained artificial intelligence model also comprises a data generation model, wherein the data generation model is used to generate an simulated voltage source and to calculate an simulated sampled signal based on the capacitive coupling structure and a transfer function of the signal processing circuit, wherein the simulated voltage source and the simulated sampled signal are used to train the signal recovery model.

20. The non-contact voltage measuring system according to claim 11, wherein the trained artificial intelligence model generates an amplitude parameter, a phase parameter and a frequency parameter based on the sampled signal, and the trained artificial intelligence model generates the recovery signal based on the amplitude parameter, the phase parameter and the frequency parameter.
